(19) United States
(12) Patent Application Publication
(10) Pub. No.: US 2024/0260396 A1
(43) Pub. Date: Aug. 1, 2024

(54) DISPLAY DEVICE AND METHOD OF MANUFACTURING THE SAME

(71) Applicant: Samsung Display Co., Ltd., Yongin-Si (KR)

(72) Inventors: JONGWOO KIM, Yongin-si (KR); Jaeheung Ha, Yongin-si (KR); Yeonguk Kim, Yongin-si (KR); Heeyeon Park, Yongin-si (KR); Changyeong Song, Yongin-si (KR); Soyoung Oh, Yongin-si (KR); Hyunsup Yoon, Yongin-si (KR); Woosuk Jung, Yongin-si (KR)

(21) Appl. No.: 18/462,399

(22) Filed: Sep. 6, 2023

(30) Foreign Application Priority Data
Jan. 27, 2023 (KR) 10-2023-0010516

(51) Int. Cl. H10K 59/80; H10K 71/40

(52) U.S. Cl. CPC H10K 59/8722; H10K 71/40

(57) ABSTRACT

A display device includes a lower substrate including a plurality of pixels and including a first area and a second area surrounding the first area on a plane, a first filler disposed on the lower substrate, overlapping the first area, and including a first catalyst, a second filler disposed on the lower substrate, overlapping the second area, disposed on a same layer as the first filler, and including a second catalyst, an upper substrate disposed on the first filler and the second filler, and a sealing member disposed between the lower substrate and the upper substrate.

### CROSS-REFERENCE TO RELATED APPLICATION

This application claims priority under 35 USC § 119 to Korean Patent Application No. 10-2023-0010516, filed on Jan. 27, 2023, in the Korean Intellectual Property Office, the content of which is herein incorporated by reference in its entirely.

### TECHNICAL FIELD

The present disclosure relates generally to a display device. More particularly, the present disclosure relates to a display device and a method of manufacturing the same.

### DISCUSSION OF RELATED ART

Display devices have experienced growth and advancement with the rise of information technology. The display device provides a connection medium between a user and information. The display devices may be using any of a variety of technologies, including for example, liquid crystal display devices (“LCD”), organic light emitting display devices (“OLED”), plasma display devices (“PDP”), or quantum dot display devices.

In order to implement a display device, a process of bonding a display substrate and an encapsulation substrate may be performed. In this case, the display device may be manufactured by applying a filler between the display substrate and the encapsulation substrate, bonding the display substrate and the encapsulation substrate together, and curing the filler by irradiating heat or light. In some cases, a curing rate of a filler disposed in the outer part of the display substrate is less than a curing rate of a filler disposed in the central part of the display substrate.

### SUMMARY

Embodiments provide a display device without a curing defect. Embodiments provide a display device having a filler that is evenly cured in a display area.

Embodiments provide a method of manufacturing the display device.

A display device according to an embodiment of the present disclosure includes a lower substrate including a plurality of pixels and including a first area and a second area surrounding the first area on a plane, a first filler disposed on the lower substrate, overlapping the first area, and including a first catalyst, a second filler disposed on the lower substrate, overlapping the second area, disposed on a same layer as the first filler, and including a second catalyst, an upper substrate disposed on the first filler and the second filler, and a sealing member disposed between the lower substrate and the upper substrate.

In an embodiment, each of the first filler and the second filler may further include a siloxane backbone.

In an embodiment, the second filler may be disposed between the first filler and the sealing member on the plane, and the sealing member may contact the second filler.

In an embodiment, each of the first catalyst and the second catalyst may include platinum (Pt).

In an embodiment, a mass ratio of the second catalyst to a total mass of the second filler may be different than a mass ratio of the first catalyst to a total mass of the first filler.

In an embodiment, the mass ratio of the first catalyst to the total mass of the first filler may be greater than about 0% and less than or equal to about 0.2% and the mass ratio of the second catalyst to the total mass of the second filler may be greater than about 0.2% and less than or equal to about 0.4%.

In an embodiment, the first filler and the second filler may have a same height.

A display device according to an embodiment of the present disclosure includes a lower substrate including a display area including a plurality of pixels and a peripheral area surrounding the display area, a first filler disposed on the lower substrate, overlapping the display area, and including a first catalyst, a second filler disposed on the lower substrate, overlapping the display area, and including a second catalyst, a sealing member disposed overlapping the peripheral area and on a same layer as the first filler and the second filler, and an upper substrate disposed on the first filler, the second filler, and the sealing member.

According to an embodiment, the second filler may overlap the peripheral area, and wherein a mass ratio of the second catalyst to a total mass of the second filler may be greater than a mass ratio of the first catalyst to a total mass of the first filler.

A method of manufacturing a display device according to an embodiment of the present disclosure includes forming an upper substrate including a first area and a second area surrounding the first area on a plane, forming a first filler overlapping the first area and including a first catalyst on the upper substrate, forming a second filler overlapping the second area and including a second catalyst on the upper substrate, forming a lower substrate including a plurality of pixels, and bonding the lower substrate and the upper substrate with the first filler and the second filler interposed therebetween.

In an embodiment, the first filler and the second filler may be formed on a same layer.

In an embodiment, the first filler and the second filler may be formed by using a jet dispenser method.

In an embodiment, the method may further include forming a sealing member on an outermost part of the upper substrate spaced apart from and surrounding the second filler before the bonding the lower substrate and the upper substrate.

In an embodiment, the method may further include curing the first filler and the second filler after the lower substrate and the upper substrate are bonded.

In an embodiment, the first filler and the second filler may be cured by a thermal curing method.

In an embodiment, a thermal curing temperature may be about 100° C. or less.

In an embodiment, the second filler may contact the sealing member after the second filler is cured.

In an embodiment, each of the first catalyst and the second catalyst may include platinum (Pt).

In an embodiment, a mass ratio of the second catalyst to a total mass of the second filler may be different than a mass ratio of the first catalyst to a total mass of the first filler.

In an embodiment, the mass ratio of the first catalyst to the total mass of the first filler may be greater than about 0% and less than or equal to about 0.2% and the mass ratio of the second catalyst to the total mass of the second filler may be greater than about 0.2% and less than or equal to about 0.4%.

In a display device according to an embodiment of the present disclosure, a concentration of a second catalyst of a second filler disposed on an outer part of a lower substrate may be greater than a concentration of a first catalyst of a first filler disposed on a central part of the lower substrate.

Accordingly, a curing rate of the second filler disposed on the outer part of the lower substrate may be increased. As a result, curing defect of fillers (e.g., the first filler and the second filler) included in the display device may be suppressed or eliminated.

In a method of manufacturing a display device according to an embodiment of the present disclosure, in a step of forming the first filler and the second filler on an upper substrate, the first filler and the second filler may be formed spaced apart from a sealing member. Accordingly, sealing defect of the display device may be suppressed or eliminated.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a cross-sectional view taken along line I-I′ of FIG. 1.

FIG. 3 is an enlarged cross-sectional view of area ‘A’ of FIG. 2.

FIG. 4 is a plan view for describing areas of a lower substrate included in a display device according to an embodiment of the present disclosure.

FIG. 5 is a plan view illustrating a display device according to an embodiment of the present disclosure.

FIG. 6 is a flowchart of a method of manufacturing a display device according to an embodiment of the present disclosure.

FIG. 7, FIG. 8, FIG. 9, FIG. 10, FIG. 11, FIG. 12, and FIG. 13 are diagrams for describing the method of manufacturing the display device of FIG. 6.

### DETAILED DESCRIPTION

Hereinafter, embodiments of the present disclosure will be described in detail with reference to the accompanying drawings. The same reference numerals are used for the same components in the drawings, and redundant descriptions of the same components may be omitted.

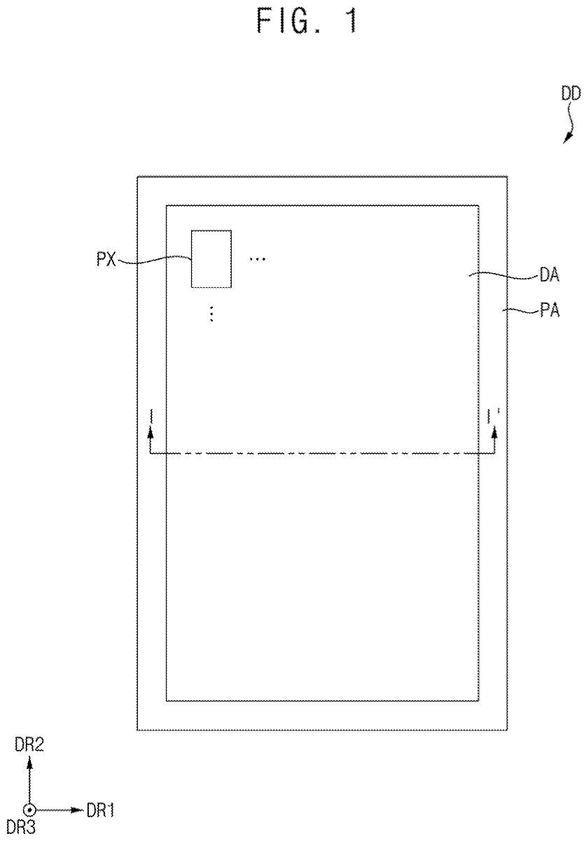

FIG. 1 is a plan view illustrating a display device according to an embodiment of the present disclosure.

In this specification, a plane may be defined by a first direction DR1 and a second direction DR2 crossing the first direction DR1. For example, the first direction DR1 and the second direction DR2 may be perpendicular to each other. A direction normal to the plane, that is, a thickness direction of a display device DD may be a third direction DR3. In other words, the third direction DR3 may be perpendicular to each of the first direction DR1 and the second direction DR2.

In this specification, it will be understood that when an element referred to as being “on”, “connected to”, or “coupled to” another element, may be directly on, connected, or coupled to the other element, or one or more intervening elements may also be present.

Referring to FIG. 1, the display device DD according to an embodiment of the present disclosure may include a display area DA and a peripheral area PA. The peripheral area PA may be adjacent to the display area DA. For example, the peripheral area PA may surround at least a part of the display area DA. The display area DA may be defined as an area capable of generating light or displaying an image by adjusting transmittance of light provided from an external light source. The peripheral area PA may be defined as an area not capable of displaying an image.

A plurality of pixels PX may be disposed in the display area DA. Each of the pixels PX may generate light according to a driving signal. The pixels PX may be arranged in a matrix along the first direction DR1 and the second direction DR2.

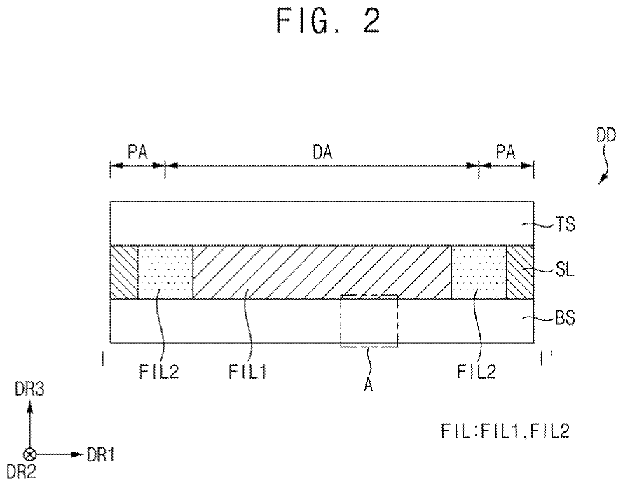

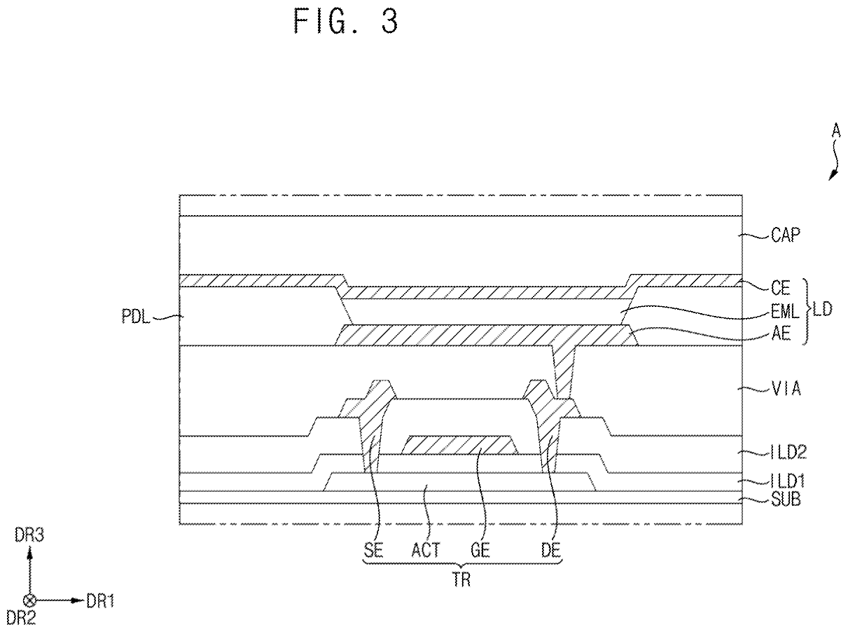

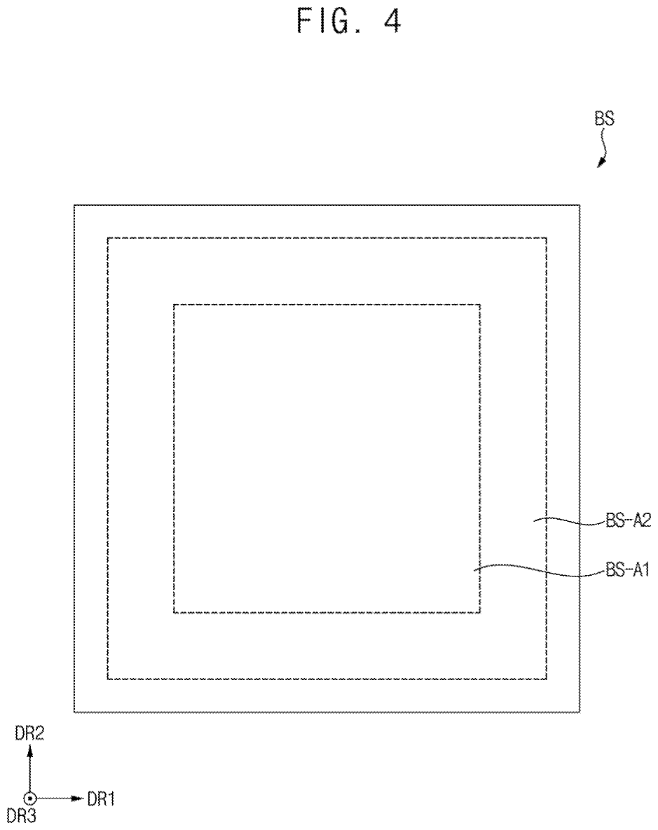

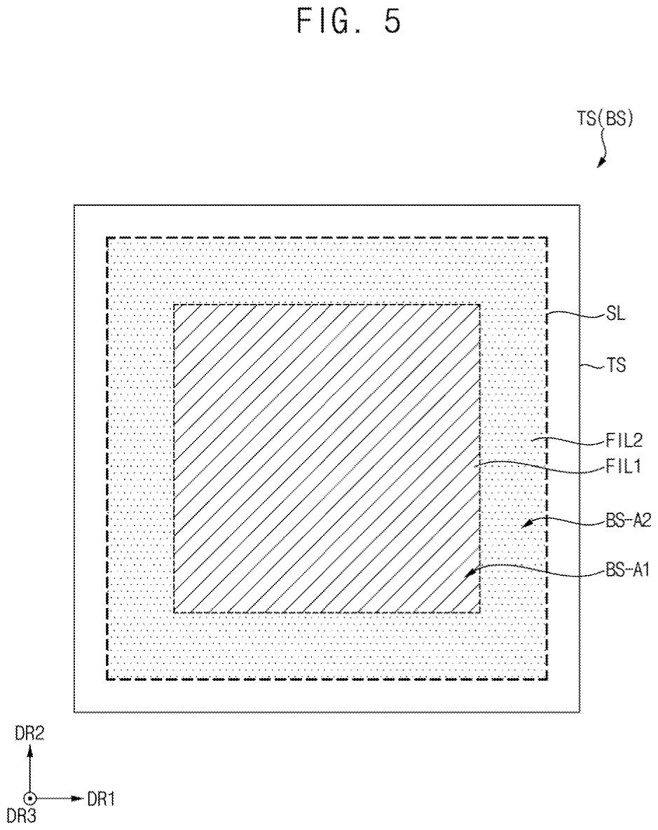

FIG. 2 is a cross-sectional view taken along line I-I′ of FIG. 1. FIG. 3 is an enlarged cross-sectional view of area ‘A’ of FIG. 2.

Referring to FIG. 2 and FIG. 3, the display device DD according to an embodiment of the present disclosure may include a lower substrate BS, a filler layer FIL, a sealing member SL, and an upper substrate TS. The lower substrate BS may include a base substrate SUB, a thin film transistor TR, a first insulating layer ILD1, a second insulating layer ILD2, a via insulating layer VIA, a light emitting element LD, a pixel defining layer PDL, and a capping layer CAP. The thin film transistor TR may include an active layer ACT, a gate electrode GE, a source electrode SE, and a drain electrode DE. The light emitting element may include a lower electrode AE, a light emitting layer EML, and an upper electrode CE.

The base substrate SUB may include a transparent material or an opaque material. The base substrate SUB may be formed of a transparent resin substrate. For example, the transparent resin substrate may be a polyimide substrate. In the case of the polyimide substrate, the polyimide substrate may include a first organic layer, a first barrier layer, and a second organic layer. The polyimide substrate may include other layers. Alternatively, the base substrate SUB may include a quartz substrate, a synthetic quartz substrate, a calcium fluoride substrate, a fluorine-doped quartz substrate, a soda-lime glass substrate, or a non-alkali glass substrate. These substrates may be used alone or in combination with each other.

A buffer layer may be disposed on the base substrate SUB. The buffer layer may reduce or prevent diffusion of metal atoms or impurities from the base substrate SUB to an upper structure (e.g., the thin film transistor TR, the light emitting element LD, etc.). For example, the buffer layer may include an organic insulating material and/or an inorganic insulating material. Alternatively, the buffer layer maybe omitted.

The active layer ACT may be disposed on the base substrate SUB. The active layer ACT may be disposed on a portion of the base substrate SUB. The active layer ACT may include, for example, an oxide semiconductor, a silicon semiconductor, or an organic semiconductor. For example, the oxide semiconductor may include indium (In), gallium (Ga), tin (Sn), zirconium (Zr), vanadium (V), hafnium (Hf), cadmium (Cd), germanium (Ge), chromium (Cr), titanium (Ti), or zinc (Zn). These materials may be used alone or in combination with each other. The silicon semiconductor may include, for example, amorphous silicon or polycrystalline silicon. The active layer ACT may include a source area, a drain area, and a channel area positioned between the source area and the drain area.

The first insulating layer ILD1 may be disposed on the active layer ACT and the base substrate SUB. The first insulating layer ILD1 may be disposed direction on the active layer ACT and an exposed portion of the base substrate SUB. The first insulating layer ILD1 may cover the active layer ACT on the base substrate SUB and may be disposed with a uniform thickness along a profile of the active layer ACT. Alternatively, the first insulating layer ILD1 may cover the active layer ACT and may have a substantially flat upper surface without a step difference around the active layer ACT.

A contact hole may be defined in the first insulating layer ILD1. One or more contact holes may be defined in the first insulating layer ILD1. The contact hole may expose a portion of the active layer ACT. The contact hole may expose a portion of an upper surface of the active layer ACT.

The first insulating layer ILD1 may include an inorganic insulating material. For example, the first insulating layer ILD1 may include a silicon compound or a metal oxide. Examples of the silicon compound may include silicon oxide (SiOₓ), silicon nitride (SiNₓ), or silicon oxynitride (SiOₓN_{y}). These materials may be used alone or in combination with each other.

The gate electrode GE may be disposed on the first insulating layer ILD1. The gate electrode GE may be disposed on a portion of the first insulating layer ILD1. The gate electrode GE may partially overlap the active layer ACT. The gate electrode GE may include, for example, a metal, an alloy, a metal nitride, a conductive metal oxide, or a transparent conductive material. Example materials that may be used as the gate electrode GE may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). These materials may be used alone or in combination with each other.

The second insulating layer ILD2 may be disposed on the gate electrode GE and the first insulating layer ILD1. The second insulating layer ILD2 may cover the gate electrode GE on the first insulating layer ILD1 and may be disposed with a uniform thickness along the profile of the gate electrode GE. Alternatively, the second insulating layer ILD2 may cover the gate electrode GE on the first insulating layer ILD1 and may have a substantially flat upper surface without a step difference around the gate electrode GE. A contact hole may be defined in the second insulating layer ILD2. The contact hole may expose a portion of the active layer ACT. The contact hole may expose a portion of an upper surface of the active layer ACT. The second insulating layer ILD2 may include an inorganic insulating material. For example, the second insulating layer ILD2 may include a silicon compound or a metal oxide.

The contact hole defined in the first insulating layer ILD1 and the contact hole defined in the second insulating layer ILD2 may be a same contact hole. One or more contact holes may be formed penetrating the first insulating layer ILD1 and the second insulating layer ILD2, which may expose one or more portions of the upper surface of the active layer ACT.

The source electrode SE and the drain electrode DE may be disposed on the second insulating layer ILD2. Each of the source electrode SE and the drain electrode DE may be electrically connected to the active layer ACT through the contact holes formed in the first insulating layer ILD1 and the second insulating layer ILD2. Each of the source electrode SE and the drain electrode DE may include, for example, a metal, an alloy, a metal nitride, a conductive metal oxide, or a transparent conductive material. These may be used alone or in combination with each other. Accordingly, the thin film transistor TR including the active layer ACT, the gate electrode GE, the source electrode SE, and the drain electrode DE may be formed.

The via insulating layer VIA may be disposed on the second insulating layer ILD2. For example, the via insulating layer VIA may be disposed on the second insulating layer ILD2 with a relatively thick thickness to cover the source electrode SE and the drain electrode DE. A contact hole may be defined in the via insulating layer VIA. The contact hole may expose a portion of the drain electrode DE. The contact hole may expose a portion of an upper surface the drain electrode DE. The via insulating layer VIA may include an organic insulating material or an inorganic insulating material. In an embodiment, the via insulating layer VIA may include an organic insulating material. For example, the via insulating layer VIA may include photoresist, polyacryl-based resin, polyimide-based resin, polyamide-based resin, siloxane-based resin, acryl-based resin, or epoxy-based resin. These materials may be used alone or in combination with each other.

The lower electrode AE may be disposed on the via insulating layer VIA. The lower electrode AE may be disposed on a portion of the via insulating layer VIA. The lower electrode AE may be electrically connected to the drain electrode DE through the contact hole formed in the via insulating layer VIA. As a result, the lower electrode AE may be electrically connected to the thin film transistor TR. The lower electrode AE may include, for example, a metal, an alloy, a metal nitride, a conductive metal oxide, or a transparent conductive material. These materials may be used alone or in combination with each other. For example, the lower electrode AE may serve as an anode electrode.

The pixel defining layer PDL may be disposed on the via insulating layer VIA. The pixel defining layer PDL may contact an edge portion of the lower electrode AE. The pixel defining layer PDL may cover an edge of the lower electrode AE. The pixel defining layer PDL may be formed on an edge portion of an upper surface of the lower electrode AE. The pixel defining layer PDL may expose a portion of an upper surface of the lower electrode AE. The pixel defining layer PDL may include an organic insulating material or an inorganic insulating material. In an embodiment, the pixel defining layer PDL may include an organic material. For example, the pixel defining layer PDL may include photoresist, polyacryl-based resin, polyimide-based resin, or acryl-based resin. These materials may be used alone or in combination with each other. In an embodiment, the pixel defining layer PDL may further include an inorganic material or an organic material including a light blocking material with black color.

The pixel defining layer PDL may expose a portion of the lower electrode AE. The light emitting layer EML may be disposed on an exposed portion the lower electrode AE. The light emitting layer EML may be disposed directly on the exposed portion the lower electrode AE. The light emitting layer EML may include one or both of an organic light emitting material and a quantum dot. For example, the organic light emitting material may include a low-molecular-weight organic compound or a high-molecular-weight organic compound. Examples of the low-molecular-weight organic compound may include, for example, copper phthalocyanine, N,N′-diphenylbenzidine, or tri-(8-hydroxyquinoline)aluminum. Examples of the high-molecular-weight organic compound may include, for example, poly(3,4-ethylenedioxythiophene), polyaniline, poly-phenylenevinylene, or polyfluorene. These materials may be used alone or in combination with each other.

The upper electrode CE may be disposed on the pixel defining layer PDL and the light emitting layer EML. The upper electrode CE may cover the pixel defining layer PDL and the light emitting layer EML and may be disposed with a uniform thickness along the profile of the pixel defining layer PDL and the light emitting layer EML. The upper electrode CE may include, for example, a metal, an alloy, a metal nitride, a conductive metal oxide, or a transparent conductive material. These materials may be used alone or in combination with each other. For example, the upper electrode CE may serve as a cathode electrode. Accordingly, the light emitting element LD including the lower electrode AE, the light emitting layer EML, and the upper electrode CE may be formed.

The capping layer CAP may be disposed on the upper electrode CE. The capping layer CAP may protect the light emitting layer EML. The capping layer CAP may have a substantially planar upper surface. The capping layer CAP may include an organic insulating material or an inorganic insulating material. For example, the capping layer CAP may include an organic insulating material such as triamine derivatives, arylenediamine derivatives, 4,4′-N,N′-triamine derivatives, 4,4′-bis(N-carbazolyl)-1,1′-biphenyl (CBP), or tris-8-hydroxyquinoline aluminum (Alq3). These materials may be used alone or in combination with each other. However, the present disclosure is not limited thereto.

The filler layer FIL may be disposed on the lower substrate BS. Specifically, the filler layer FIL may be disposed on the capping layer CAP. For example, the filler layer FIL may be disposed on the upper surface of the capping layer CAP. The filler layer FIL may include a first filler FIL1 and a second filler FIL2. In an embodiment, the first filler FIL1 and the second filler FIL2 may be disposed on a same layer. As illustrated in FIG. 2, a thickness of the first filler FIL1 and a thickness of the second filler FIL2 may be the same. That is, a height of the first filler FIL1 and a height of the second filler FIL2 may be the same. However, embodiments of the present disclosure are not limited thereto, and the thickness of the first filler FIL1 and the thickness of the second filler FIL2 may be different from each other.

In an embodiment, the first filler FIL1 may be disposed overlapping a portion of the display area DA, and the second filler FIL2 may be disposed overlapping a portion of the display area DA and a portion of the peripheral area PA.

A detailed description of the first filler FIL1 and the second filler FIL2 is described herein with reference to FIG. 4 and FIG. 5.

The sealing member SL may be disposed between the lower substrate BS and the upper substrate TS. The sealing member SL may be disposed in the peripheral area PA. Specifically, the sealing member SL may be disposed along edges of the lower substrate BS and the upper substrate TS in the peripheral area PA. The sealing member SL may surround the display area DA on a plane. The lower substrate BS and the upper substrate TS may be bonded together by the sealing member SL. Thus, a height of the sealing member SL may be the same as the height of the first filler FIL1 and the second filler FIL2.

The sealing member SL may include an inorganic material. For example, the sealing member SL may be a glass frit. The glass frit may include, for example, a powdered glass raw material or silicon oxide. The sealing member SL may be a paste including, for example, silicon oxide, a laser or infrared absorbing material, an organic binder, or a filler for reducing a thermal expansion coefficient. When the sealing member SL is irradiated, for example, by a laser, the sealing member SL may be melted and hardened. Accordingly, the lower substrate BS and the upper substrate TS may be bonded.

The upper substrate TS may be disposed on the filler layer FIL. The upper substrate TS may resist or prevent impurities, moisture and the like from permeating the light emitting element LD from the outside. The upper substrate TS may have a single-layer structure. For example, the upper substrate TS may be glass. Alternatively, the upper substrate TS may have a multi-layer structure. For example, the upper substrate TS may have a structure in which a first inorganic encapsulation layer, an organic encapsulation layer, and a second inorganic encapsulation layer are sequentially stacked.

In addition, although the display device DD of the present disclosure is described as an organic light emitting display device (“OLED”), the present disclosure is not limited thereto. In other embodiments, the display device DD may include, for example, a liquid crystal display device (“LCD”), a field emission display device (“FED”), a plasma display device (“PDP”), an electrophoretic image display device (“EPD”), an inorganic light emitting display device (“ILED”), or a quantum dot display device.

FIG. 4 is a plan view for describing areas of a lower substrate according to some embodiments, which may be included in the display device of FIG. 2. FIG. 5 is a plan view illustrating the display device of FIG. 2 according to some embodiments. For example, FIG. 5 is a plan view of the upper substrate TS of FIG. 2 viewed from a direction opposite to the third direction DR3.

Referring to FIG. 4, the lower substrate BS may include a first area BS-A1 and a second area BS-A2. The second area BS-A2 may surround the first area BS-A1 on a plane. That is, the first area BS-A1 may be positioned at a central part of the lower substrate BS, and the second area BS-A2 may be positioned at an outer part of the lower substrate BS.

Referring to FIG. 5, the first filler FIL1 may be disposed on the lower substrate BS in the first area BS-A1. That is, the first filler FIL1 may overlap the first area BS-A1. The second filler FIL2 may be disposed on the lower substrate BS in the second area BS-A2. That is, the second filler FIL2 may overlap the second area BS-A2.

Each of the first filler FIL1 and the second filler FIL2 may be formed using a jet dispenser method. Each of the first filler FIL1 and the second filler FIL2 may include a silicon-based material. When each of the first filler FIL1 and the second filler FIL2 includes a silicon-based material, chemical penetration of the first filler FIL1 and the second filler FIL2 into the capping layer (e.g., the capping layer CAP of FIG. 3) may be reduced or prevented. When each of the first filler FIL1 and the second filler FIL2 includes a silicon-based material, wear of the capping layer by the first filler FIL1 and the second filler FIL2 may be reduced or prevented.

The first filler FIL1 may include, for example, a monomer, a linker, an initiator, and an inhibitor. In an embodiment, the first filler FIL1 may include a siloxane backbone. Specifically, the first filler FIL1 may include a polysiloxane having a vinyl group as the monomer. The monomer may be selected from various types of monomers. The monomer may include three or more different monomers. The linker may include a siloxane oligomer.

The first filler FIL1 may include a first catalyst. Specifically, the first filler FIL1 may include the first catalyst as an initiator used to produce a curing effect. The first catalyst may function as a curing agent by promoting a reaction in which the monomer and the linker react to form a Si—C chemical bond. In an embodiment, the first catalyst may include platinum (Pt).

In an embodiment, a mass ratio of the first catalyst to a total mass of the first filler FIL1 may be greater than about 0% and less than or equal to about 0.2%. When the mass ratio of the first catalyst exceeds about 0.2%, the first filler FIL1 may be hardened before sufficiently spreading on the lower substrate BS, and the first filler FIL1 may not completely cover the lower substrate BS. That is, when the mass ratio of the first catalyst exceeds about 0.2%, the first filler FIL1 may be hardened before sufficiently spreading on the lower substrate BS, and the first filler FIL1 may not completely cover the first area BS-A1 of the lower substrate BS. As a result, defects in the display device DD may occur.

The second filler FIL2 may include a monomer, a linker, an initiator, and an inhibitor. In an embodiment, the second filler FIL2 may include a siloxane backbone. Specifically, the second filler FIL2 may include a polysiloxane having a vinyl group as the monomer. The monomer may be selected from various types of monomers. The monomer may include three or more different monomers. The linker may include a siloxane oligomer.

The second filler FIL2 may include a second catalyst. Specifically, the second filler FIL2 may include the second catalyst as an initiator used to produce a curing effect. The second catalyst may function as a curing agent by promoting a reaction in which the monomer and the linker react to form a Si—C chemical bond. In an embodiment, the second catalyst may include platinum (Pt).

The spreading speeds of components of the filler (e.g., the monomer, the linker, and the initiator, etc.) on the lower substrate BS may be different from each other. Accordingly, the curing rate of the filler disposed on the outer part of the lower substrate BS may be less than the curing rate of the filler disposed on the central part of the lower substrate BS. That is, the filler disposed on the lower substrate BS may not be evenly cured. As a result, a curing defect of the filler may occur.

According to embodiments of the present disclosure, it may be possible to compensate for the different spreading speeds of the components of the filler, wherein a concentration of the second catalyst of the second filler FIL2 disposed on the outer part of the lower substrate BS may be different than a concentration of the first catalyst of the first filler FIL1 disposed on the central part of the lower substrate BS. For example, the concentration of the second catalyst of the second filler FIL2 disposed on the outer part of the lower substrate BS may be greater than the concentration of the first catalyst of the first filler FIL1 disposed on the central part of the lower substrate BS. Accordingly, the curing rate of the filler (e.g., the second filler FIL2) disposed on the outer part of the lower substrate BS may adjusted. For example, the curing rate of the filler (e.g., the second filler FIL2) disposed on the outer part of the lower substrate BS may be increased. For example, the curing rate of the filler (e.g., the second filler FIL2) disposed on the outer part of the lower substrate BS may be increased and the filler layer FIL disposed on the lower substrate BS may be evenly cured across the lower substrate BS. As described herein, even in an example where the curing rate of the second filler FIL2 is increased, the curing rate of the second filler FIL2 may be less than a curing rate of the first filler FIL1. By increasing the curing rate of the second filler FIL2, the curing rate of the filler layer FIL in the outer part of the lower substrate BS may approach the curing rate of the filler layer FIL in the central part of the lower substrate BS and a curing defect of the filler may be suppressed or eliminated.

In an embodiment, a mass ratio of the second catalyst to a total mass of the second filler FIL2 may be greater than about 0.2% and less than or equal to about 0.4%. When the mass ratio of the second catalyst is about 0.2% or less, the second filler FIL2 disposed on the outer part of the lower substrate BS may not be sufficiently cured. When the mass ratio of the second catalyst is greater than about 0.4%, the second filler FIL2 may be hardened before sufficiently spreading on the lower substrate BS, and the second filler FIL2 may not completely cover the lower substrate BS. For example, when the mass ratio of the second catalyst is greater than about 0.4%, the second filler FIL2 may be hardened before sufficiently spreading on the lower substrate BS, and the second filler FIL2 may not evenly cover the lower substrate BS. By tuning a mass ratio of the second catalyst to a total mass of the second filler FIL2, defects in the display device DD may be suppressed or eliminated.

The sealing member SL may be disposed between the lower substrate BS and the upper substrate TS. The lower substrate BS and the upper substrate TS may be bonded together through the sealing member SL. In an embodiment, the sealing member SL may contact the second filler FIL2. The sealing member SL may contact an outer portion of the second filler FIL2. As described herein with reference to FIG. 8 and FIG. 9, when the second filler FIL2 is applied to the upper substrate TS by the jet dispenser method, the second filler FIL2 may be applied spaced apart from the sealing member SL. However, after curing the second filler FIL2, the second filler FIL2 may contact the sealing member SL. That is, after curing the second filler FIL2, the second filler FIL2 may contact an inner portion of the sealing member SL.

The upper substrate TS may be disposed on the first filler FIL1 and the second filler FIL2.

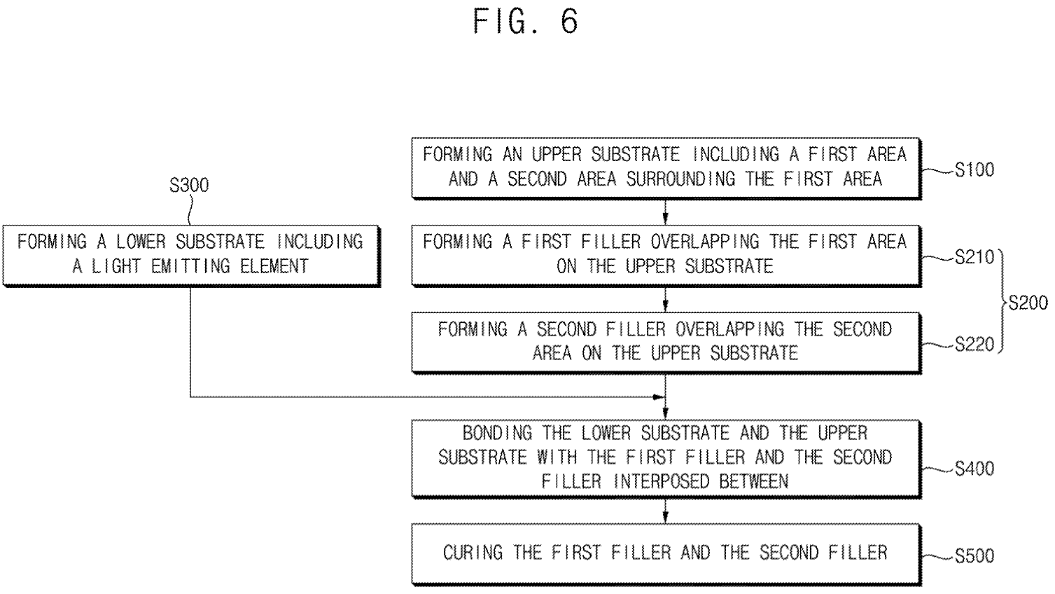

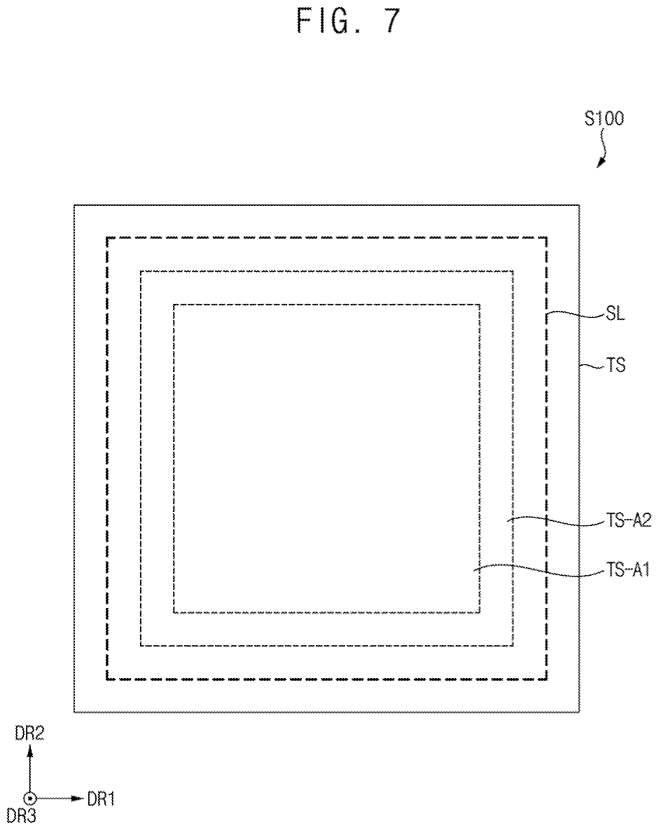

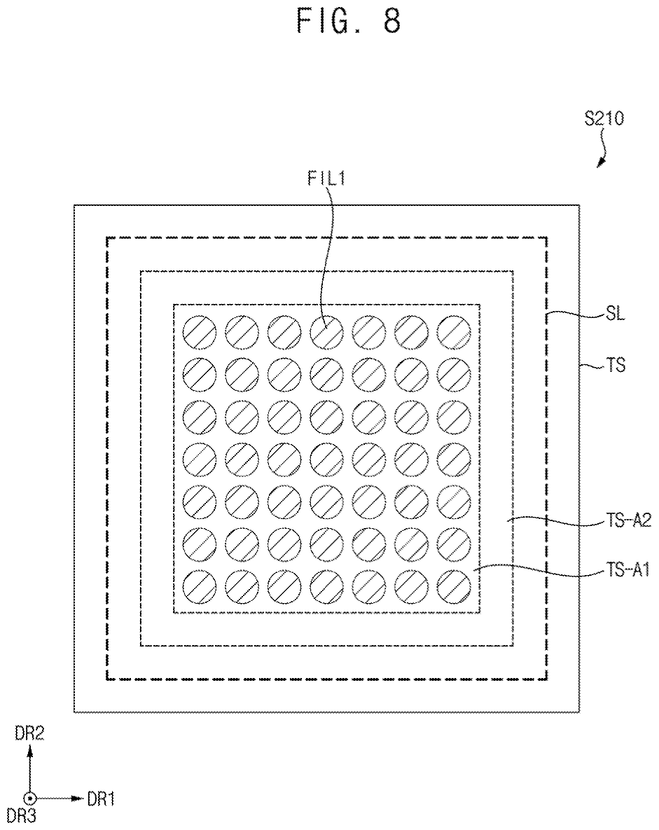

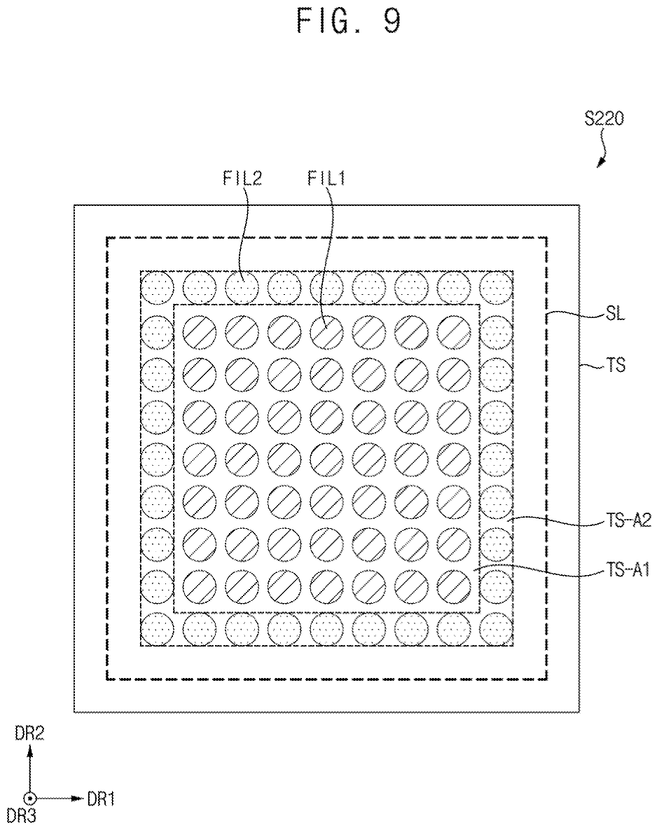

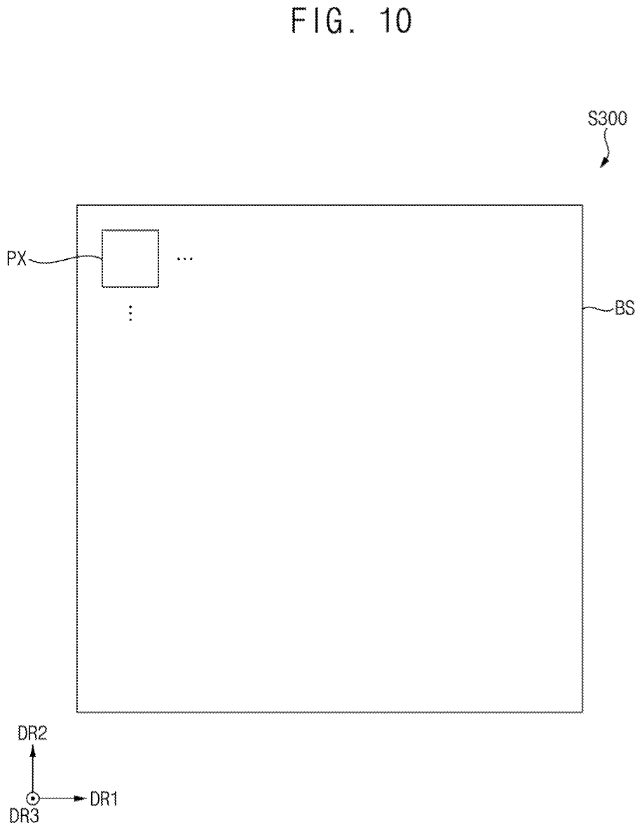

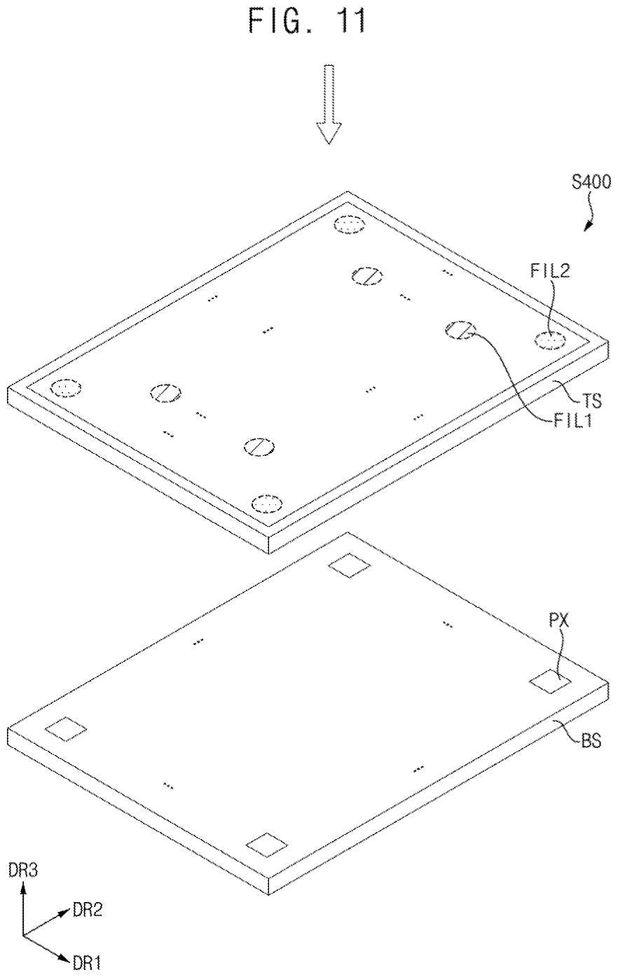

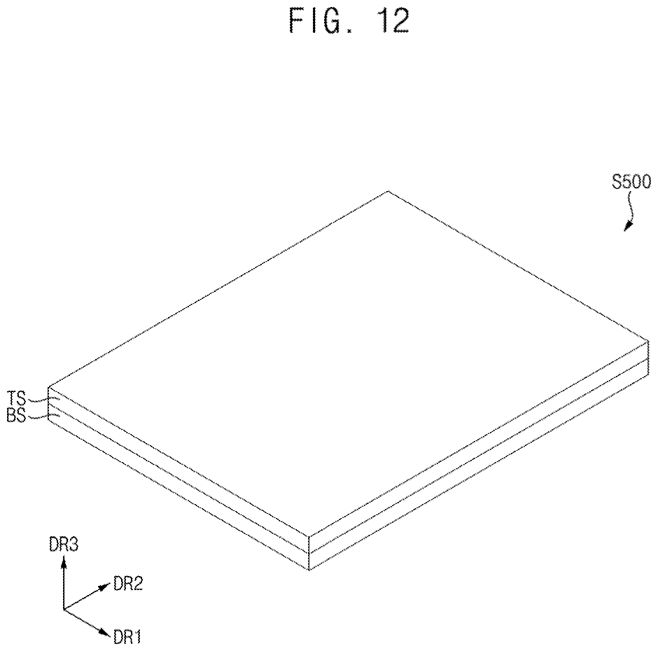

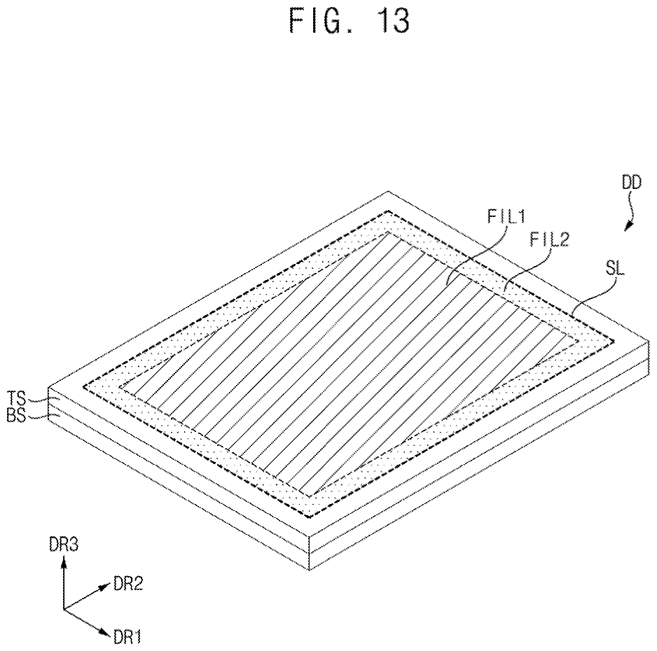

FIG. 6 is a flowchart of a method of manufacturing a display device according to an embodiment of the present disclosure. FIG. 7, FIG. 8, FIG. 9, FIG. 10, FIG. 11, FIG. 12, and FIG. 13 are diagrams for describing the method of manufacturing the display device of FIG. 6.

Referring to FIG. 6, a method of manufacturing a display device according to an embodiment of the present disclosure may include forming an upper substrate TS (S100), forming a first filler FIL1 and a second filler FIL2 (S200), forming a lower substrate BS (S300), bonding the lower substrate BS to the upper substrate TS (S400) with the first filler FIL1 and the second filler FIL2 interposed therebetween, and curing the first filler FIL1 and the second filler FIL2 (S500).

Referring to FIG. 7, the upper substrate TS including a first area TS-A1 and a second area TS-A2 may be formed (S100).

The upper substrate TS may include a transparent plate or a transparent film. The upper substrate TS may include an inorganic material such as glass and/or quartz. The upper substrate TS may include the first area TS-A1 and the second area TS-A2 surrounding the first area TS-A1. That is, the first area TS-A1 may be positioned at a central part of the upper substrate TS, and the second area TS-A2 may be positioned at an outer part of the upper substrate TS.

The upper substrate TS may further include a sealing member SL disposed on an outermost part of the upper substrate TS. The outermost portion of the upper substrate TS may surround the second area TS-A2 positioned at the outer part of the upper substrate TS. The sealing member SL may include an inorganic material. For example, the sealing member SL may include a glass frit.

Referring to FIG. 8 and FIG. 9, the first filler FIL1 and the second filler FIL2 may be formed on the upper substrate TS (S200).

As illustrated in FIG. 8, the first filler FIL1 in the first area TS-A1 may be formed on the upper substrate TS (S210).

The first filler FIL1 may include a monomer, a linker, an initiator, and an inhibitor. In an embodiment, the first filler FIL1 may include a siloxane backbone. Specifically, the first filler FIL1 may include a polysiloxane having a vinyl group as the monomer.

The first filler FIL1 may include a first catalyst. Specifically, the first filler FIL1 may include the first catalyst as the initiator. In an embodiment, the first catalyst may include platinum (Pt). For example, a mass ratio of the first catalyst to a total mass of the first filler FIL1 may be greater than about 0% and less than or equal to about 0.2%.

As illustrated in FIG. 9, the second filler FIL2 in the second area TS-A2 may be formed on the upper substrate TS (S220).

The second filler FIL2 may include a monomer, a linker, an initiator, and an inhibitor. In an embodiment, the second filler FIL2 may include a siloxane backbone. Specifically, the second filler FIL2 may include a polysiloxane having a vinyl group as the monomer.

The second filler FIL2 may include a second catalyst. Specifically, the second filler FIL2 may include the second catalyst as the initiator. In an embodiment, the second catalyst may include platinum (Pt). For example, a mass ratio of the second catalyst to a total mass of the second filler FIL2 may be greater than about 0.2% and less than or equal to about 0.4%.

The forming the first filler FIL1 (S210) and the forming the second filler FIL2 (S220) may be separately performed. For example, the first filler FIL1 may be deposited in the first area TS-A1, and then the second filler FIL2 may be deposited in the second area TS-A2. In another example, the first filler FIL1 may be deposited after a deposition of the second filler FIL2. In another example, the forming the first filler FIL1 (S210) and the forming the second filler FIL2 (S220) may be performed simultaneously.

The first filler FIL1 and the second filler FIL2 may be formed on a same layer. In an embodiment, the first filler FIL1 and the second filler FIL2 may be formed using a jet dispenser method. Accordingly, the first filler FIL1 and the second filler FIL2 may be deposited as a plurality of dots.

In an embodiment, each of the first filler FIL1 and the second filler FIL2 may be formed spaced apart from the sealing member SL. The second filler FIL2 may be formed between the first filler FIL1 and the sealing member SL on a plane. In bonding the lower substrate BS and the upper substrate TS (S400), the sealing member SL may be irradiated with a laser beam.

At this time, exposure of the first filler FIL1 and the second filler FIL2 to the laser beam may be reduced or prevented. That is, by forming each of the first filler FIL1 and the second filler FIL2 spaced apart from the sealing member SL, the sealing member SL may be irradiated without irradiating the first filler FIL1 and the second filler FIL2. By separately irradiating the sealing member SL, a sealing defect of the display device may be suppressed or eliminated.

Referring to FIG. 10, the lower substrate BS including a plurality of pixels PX may be formed (S300). The lower substrate BS may face the upper substrate TS as illustrated in FIG. 11 and described herein.

Each of the pixels PX may generate light according to a driving signal. The pixels PX may be arranged in a matrix along the first direction DR1 and the second direction DR2.

As described above with reference to FIG. 3, the lower substrate BS may include the base substrate SUB, the thin film transistor TR, the first insulating layer ILD1, the second insulating layer ILD2, the via insulating layer VIA, the light emitting element LD, the pixel defining layer PDL, and the capping layer CAP. That is, the thin film transistor TR, the first insulating layer ILD1, the second insulating layer ILD2, and the via insulating layer VIA may be formed on the base substrate SUB. In addition, the light emitting element LD, the pixel defining layer PDL, and the capping layer CAP may be formed on the via insulating layer VIA.

Referring to FIG. 11, the lower substrate BS and the upper substrate TS may be bonded together with the first filler FIL1 and the second filler FIL2 interposed therebetween (S400).

The sealing member SL may be irradiated by the laser to bond the lower substrate BS and the upper substrate TS together. When the sealing member SL is irradiated by the laser, the sealing member SL may be melted and cured. Accordingly, the lower substrate BS and the upper substrate TS may be bonded together.

Referring to FIG. 12 and FIG. 13, after the bonding the lower substrate BS and the upper substrate TS (S400), the first filler FIL1 and the second filler FIL2 may be cured (S500).

The first filler FIL1 and the second filler FIL2 may be cured by thermal curing, ultra-violet (UV) curing, etc. In an embodiment, the first filler FIL1 and the second filler FIL2 may be cured by a thermal curing method. In the curing step, each of the first catalyst of the first filler FIL1 and the second catalyst of the second filler FIL2 may be used as a curing agent. In an embodiment, a thermal curing temperature may be less than or equal to about 100° C. When the thermal curing temperature exceeds about 100° C., the light emitting element (e.g., the light emitting element LD of FIG. 3) may be damaged.

As illustrated in FIG. 13, after the curing the first filler FIL1 and the second filler FIL2 (S500), the second filler FIL2 may contact the sealing member SL.

In the forming the second filler FIL2 on the upper substrate TS (S220), the second filler FIL2 may be applied spaced apart from the sealing member SL. After the bonding the lower substrate BS and the upper substrate TS (S400), the second filler FIL2 may spread in a direction from a central part of the lower substrate BS toward an outermost part of the lower substrate BS of an outer part of the lower substrate BS. As a result, after the curing the first filler FIL1 and the second filler FIL2 (S500), the second filler FIL2 may contact the sealing member SL disposed on the outermost part of the lower substrate BS. That is, an outer portion of the second filler FIL2 may contact an inner portion of the sealing member SL on a plane.

Hereinafter, an effect of the present disclosure will be described with reference to FIG. 2 and Table 1 below.

Data presented in Table 1 shows the curing rate of the filler layer FIL disposed on the lower substrate BS measured according to the position on the lower substrate BS. Data for a Comparative Example and an Example according to an embodiment are presented. Pt intensity measures the curing rate of the filler layer FIL. An activity of a platinum (Pt) catalyst included in the filler layer FIL may increase with the Pt intensity. That is, if the Pt intensity is high, it may be interpreted that the curing rate of the filler layer FIL is high.

In a display device according to the Example (e.g., the display device DD of FIG. 2), the first filler FIL1 may be formed on the central part of the lower substrate BS, and the second filler FIL2 may be formed on the outer part of the lower substrate BS. The first filler FIL1 may include a polysiloxane having three types of vinyl groups as a monomer and platinum (Pt) catalyst as an initiator whose mass ratio to the total mass of the first filler FIL1 is about 0.2%. The second filler FIL2 may include a polysiloxane having three types of vinyl groups as a monomer and platinum (Pt) catalyst as an initiator whose mass ratio to the total mass of the second filler FIL2 is about 0.4%.

In a display device according to the Comparative Example, a filler is formed on the lower substrate. The filler includes a polysiloxane having three types of vinyl groups as a monomer and platinum (Pt) catalyst as an initiator whose mass ratio to the total mass of the filler is about 0.2%.

As a result, referring to Table 1 below, the Pt intensity of the display device according to the Comparative Example has a value of about 4.18×10³ on the central part of the lower substrate and about 1.30×10³ on the outer part of the lower substrate. That is, a ratio of the Pt intensity value on the outer part of the lower substrate to the Pt intensity value on the central part of the lower substrate is about 31.0%.

The Pt intensity of the display device according to the Example may have a value of about 4.04×10³ on the central part of the lower substrate BS and about 2.29×10³ on the outer part of the lower substrate BS. That is, a ratio of the Pt intensity value on the outer part of the lower substrate BS to the Pt intensity value on the central part of the lower substrate BS may be about 56.7%.

TABLE 1

| | Comparative Example | | Example | |
|---|---|---|---|---|
| | Central part | Outer part | Central part | Outer part |
| Pt intensity (×10³) | 4.18 | 1.30 | 4.04 | 2.29 |

| | | |
|---|---|---|
| Ratio of the outer | 31.0 | 56.7 |
| part to the central | | |
| part (%) | | |

From this data, the display device DD according to an embodiment of the present disclosure may have an effect of increasing the curing rate of the second filler FIL2 disposed on the outer part of the lower substrate BS by increasing a concentration of the second catalyst of the second filler FIL2 disposed on the outer part of the lower substrate BS relative to a concentration of the first catalyst of the first filler FIL1 disposed on the central part of the lower substrate BS.

Embodiments of the present disclosure may be applied to various display devices. For example, the present disclosure may be applicable to various display devices such as display devices for vehicles, ships and aircraft, portable communication devices, display devices for exhibition or information transmission, medical display devices, and the like.

The foregoing is illustrative of embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims.

What is claimed is:

1. A display device comprising:
a lower substrate including a plurality of pixels and including a first area and a second area surrounding the first area on a plane;
a first filler disposed on the lower substrate, overlapping the first area, and including a first catalyst;
a second filler disposed on the lower substrate, overlapping the second area, disposed on a same layer as the first filler, and including a second catalyst;
an upper substrate disposed on the first filler and the second filler; and
a sealing member disposed between the lower substrate and the upper substrate.

2. The display device of claim 1, wherein each of the first filler and the second filler further includes a siloxane backbone.

3. The display device of claim 1, wherein the second filler is disposed between the first filler and the sealing member on the plane, and the sealing member contacts the second filler.

4. The display device of claim 1, wherein each of the first catalyst and the second catalyst includes platinum (Pt).

5. The display device of claim 1, wherein a mass ratio of the second catalyst to a total mass of the second filler is different than a mass ratio of the first catalyst to a total mass of the first filler.

6. The display device of claim 5, wherein the mass ratio of the first catalyst to the total mass of the first filler is greater than about 0% and less than or equal to about 0.2% and the mass ratio of the second catalyst to the total mass of the second filler is greater than about 0.2% and less than or equal to about 0.4%.

7. The display device of claim 1, wherein the first filler and the second filler have a same height.

8. A display device comprising:
a lower substrate including a display area including a plurality of pixels and a peripheral area surrounding the display area;
a first filler disposed on the lower substrate, overlapping the display area, and including a first catalyst;
a second filler disposed on the lower substrate, overlapping the display area, and including a second catalyst;
a sealing member disposed overlapping the peripheral area and on a same layer as the first filler and the second filler; and
an upper substrate disposed on the first filler, the second filler, and the sealing member.

9. The display device of claim 8, wherein the second filler overlaps the peripheral area, and wherein a mass ratio of the second catalyst to a total mass of the second filler is greater than a mass ratio of the first catalyst to a total mass of the first filler.

10. A method of manufacturing a display device, the method comprising:
forming an upper substrate including a first area and a second area surrounding the first area on a plane;
forming a first filler overlapping the first area and including a first catalyst on the upper substrate;
forming a second filler overlapping the second area and including a second catalyst on the upper substrate;
forming a lower substrate including a plurality of pixels; and
bonding the lower substrate and the upper substrate with the first filler and the second filler interposed therebetween.

11. The method of claim 10, wherein the first filler and the second filler are formed on a same layer.

12. The method of claim 10, wherein the first filler and the second filler are formed by using a jet dispenser method.

13. The method of claim 10, further comprising forming a sealing member on an outermost part of the upper substrate spaced apart from and surrounding the second filler before the lower substrate and the upper substrate are bonded.

14. The method of claim 13, further comprising curing the first filler and the second filler after the lower substrate and the upper substrate are bonded.

15. The method of claim 14, wherein the first filler and the second filler are cured by a thermal curing method.

16. The method of claim 15, wherein a thermal curing temperature is about 100° C. or less.

17. The method of claim 14, wherein the second filler contacts the sealing member after the second filler is cured.

18. The method of claim 10, wherein each of the first catalyst and the second catalyst includes platinum (Pt).

19. The method of claim 10, wherein a mass ratio of the second catalyst to a total mass of the second filler is different than a mass ratio of the first catalyst to a total mass of the first filler.

20. The method of claim 19, wherein the mass ratio of the first catalyst to the total mass of the first filler is greater than about 0% and less than or equal to about 0.2% and the mass ratio of the second catalyst to the total mass of the second filler is greater than about 0.2% and less than or equal to about 0.4%.
